(19) United States
(12) Patent Application Publication
(10) Pub. No.: US 2024/0224439 A1
(43) Pub. Date: Jul. 4, 2024

(54) FOLDABLE ELECTRONIC CONTROL DEVICE

(71) Applicant: Hyundai Kefico Corporation, Gunpo (KR)

(72) Inventor: Wan Kyu Lee, Suwon (KR)

(21) Appl. No.: 18/397,417

(22) Filed: Dec. 27, 2023

(30) Foreign Application Priority Data
Dec. 28, 2022 (KR) 10-2022-0187825

(51) Int. Cl. H05K 5/00

(52) U.S. Cl. CPC H05K 5/0069; H05K 5/0021; H05K 5/0043; H05K 5/0052; H05K 1/118; H05K 5/0008; H05K 2201/055

(57) ABSTRACT

A foldable electronic control device includes a housing having a body and a cover configured to be opened and closed in a foldable manner. First and second boards are fastened to the body and the cover, respectively, and configured to be disconnected from each other when the housing is unfolded and connected to each other in a stacked state when the housing is folded. A flexible cable electrically connects the first board and the second board when the housing is folded.

### CROSS-REFERENCE TO RELATED APPLICATION

This application claims under 35 U.S.C. § 119(a) the benefit of Korean Patent Application No. 10-2022-0187825, filed on Dec. 28, 2022, which is incorporated by reference herein.

### BACKGROUND

### (a) Technical Field

The present disclosure relates to a foldable electronic control device.

### (b) Description of the Related Art

A typical foldable electronic control device may be folded or unfolded about a hinge structure.

In order to construct a stack of printed circuit boards (PCBs) in a housing to reduce costs, it has been traditionally required to provide connectors (i.e., board-to-board connectors) between the PCBs or solder a separate cable to connectors.

In the related art, it has been attempted to construct a stack of PCBs to reduce costs. However, a complicated configuration for connecting the PCBs may have problems (e.g., unnecessary material costs and labor hours), and PCBs provided in a stack may be problematic in terms of durability.

### SUMMARY

Various embodiments are directed to a foldable electronic control device having a configuration in which a plurality of PCBs provided therein may be in a connected or disconnected state depending on the folded or unfolded state of a housing.

The objectives of the present disclosure are not limited to the aforementioned description, and other objectives not explicitly described herein will be apparent to a person having ordinary skill in the art from the description provided hereinafter.

A foldable electronic control device according to an embodiment of the present disclosure includes: a housing including a body and a cover configured to be opened and closed in a foldable manner; first and second boards fastened to the body and the cover, respectively, and configured to be disconnected from each other when the housing is unfolded and connected to each other when the housing is folded; and a flexible cable electrically connecting the first board and the second board when the housing is folded.

The first and second boards may be configured to be connected to each other in a stacked state when the housing is folded.

The flexible cable may include a flexible printed circuit (FPC).

The flexible cable may be fixed to a connecting portion between the body and the cover by fusion.

The flexible cable may be fastened to a connecting portion between the body and the cover by bolting.

The flexible cable may be fused to a connecting portion between the body and the cover while wrapping around the entire connecting portion.

The flexible cable may be fixed to a connecting portion between the body and the cover while having a ‘⊂’ shape.

The flexible cable may maintain a ‘∩’ shape in a case of unfolding between the body and the cover and maintains a ‘⊂’ shape in a case of folding between the body and the cover.

Each of the first and second boards may include flip-chip type solder bumps on a portion of the first and second boards engaging with the flexible cable.

The body may include a plurality of first backing rods protruding therefrom to extend through predetermined portions of the first board. The cover may include a plurality of second backing rods protruding therefrom to extend through predetermined portions of the second board.

The cover may cover the body, the first backing rods support the second board, and the second backing rods support the first board.

The body may include an external connection connector connected to the first board.

The cover may have a structure in which a portion of the cover engaging with the connector is depressed.

A vehicle may include the above-described foldable electronic control device.

A foldable electronic control device according to another embodiment of the present disclosure includes: a housing including a body having an accommodation space therein and a cover configured to cover the body in a foldable manner; a first board connected to the body; a second board connected to the cover; and a flexible cable electrically connecting the first board and the second board.

The flexible cable may be located on a connecting portion between the body and the cover.

The housing may have a structure in which the body and the cover are fastened to each other by snap fitting.

Each of the first and second boards may include flip-chip type solder bumps on a portion of the first and second boards engaging with the flexible cable.

The connecting portion between the body and the cover may include a plurality of protrusions on predetermined portions, and each of the first and second boards may include a plurality of fixing recesses configured to engage with the protrusions.

The protrusions may be configured to extend through the flexible cable.

Each of the protrusions may have a tapered structure, a width of which gradually decreases in an outward direction from the connecting portion.

Predetermined outer circumferential portions of the protrusions may be depressed to form fastening recesses into which the flexible cable is fitted.

A vehicle may include the above-described foldable electronic control device.

According to the present disclosure, cost reduction may be achieved using a relatively simple structure in which a plurality of PCBs (e.g., first and second boards) provided therein may be in a connected or disconnected state depending on the folded or unfolded state of a housing.

In particular, the flexible cable, which is a flexible printed circuit (FPC), may be provided as terminals on the connecting portions between the body and the cover of the housing, thereby facilitating the connection between the stacked PCBs. In addition, the durability problem may also be advantageously overcome.

### BRIEF DESCRIPTION OF THE DRAWINGS

FIG. 1 is a perspective view schematically illustrating a folded shape of a foldable electronic control device according to embodiments of the present disclosure.

FIG. 2 is a cross-sectional view illustrating the part A-A′ illustrated in FIG. 1.

FIG. 3 is a perspective view schematically illustrating an unfolded shape of the foldable electronic control device according to embodiments of the present disclosure.

FIG. 4 is an enlarged view of the part B illustrated in FIG. 1.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “—er”, “—or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

The above and other advantages and features of the present disclosure, as well as methods of realizing the same, will be more clearly understood from the following detailed description of embodiments when taken in conjunction with the accompanying drawings. However, the present disclosure is not limited to specific embodiments to be described hereinafter but may be embodied in a variety of different forms. Rather, these embodiments are provided so that the description of the present disclosure will be complete and will fully convey the scope of the present disclosure to a person having ordinary skill in the art to which the present disclosure pertains. The present disclosure shall be defined by the Claims. The terminologies used herein are for the purpose of describing particular embodiments only and are not intended to limit the present disclosure. As used herein, singular forms are intended to include plural forms as well, unless the context clearly indicates otherwise.

Hereinafter, exemplary embodiments of the present disclosure will be described with reference to the accompanying drawings.

### Coordinate System

X-, y-, and z-axes shown in the figures represent a three-dimensional Cartesian coordinate system that displays the coordinates of a point or a vector relative to straight-line coordinate axes intersecting each other at right angles. In this coordinate system, for ease of description, the x-axis, the y-axis, and the z-axis may be described as being indicative of the width direction, the length direction, and the up and down direction of a housing in the configuration of the foldable electronic control device, respectively.

In addition, the directions of each of the x-, y-, and z-axes include a positive direction and a negative direction.

The positive and negative directions of each of the axes may be described in terms of the same or different specific reference points for ease of description.

For example, in the present disclosure, the positive direction of the x-axis refers to the right in a lateral direction, and the negative direction of the x-axis refers to the left in the lateral direction. However, the positive and negative directions may be determined through any reference point, and the reference point may vary depending on the respective structure.

Further, the coordinate system shown in each figure is only illustrated as an example for ease of description, and each configuration of the present disclosure is not limited to the location of the coordinate system.

### Foldable Electronic Control Device

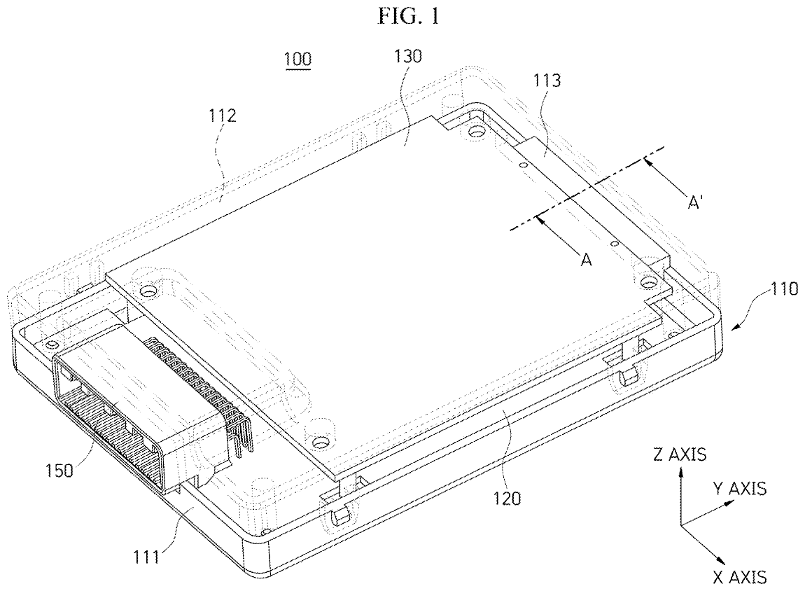

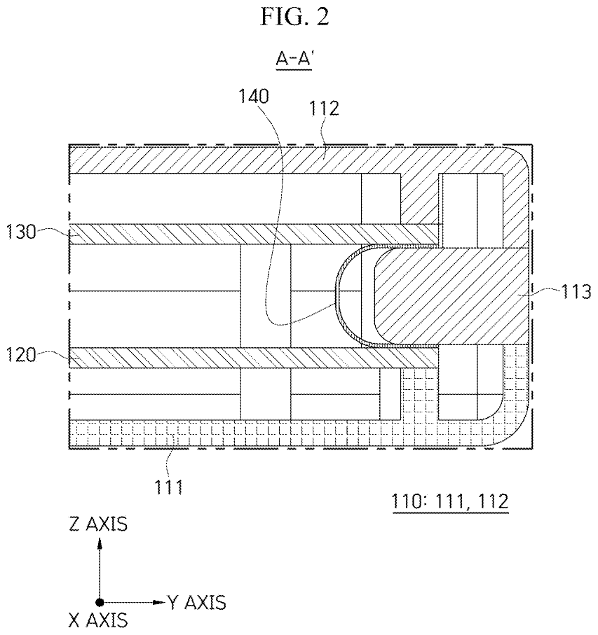

FIG. 1 is a perspective view schematically illustrating a folded shape of a foldable electronic control device according to embodiments of the present disclosure, and FIG. 2 is a cross-sectional view illustrating the part A-A′ illustrated in FIG. 1.

A foldable electronic control device 100 according to embodiments of the present disclosure is configured such that terminals (e.g., a flexible cable) are separated from PCBs (i.e., first and second boards) in order to selectively connect the PCBs. Accordingly, the foldable electronic control device 100 may avoid a complicated structure for connections and overcome the durability problems (e.g., a circuit connection problem) due to frequent folding of a housing. That is, the foldable electronic control device 100 does not provide a direct connection between the PCBs (i.e., a board-to-board connection) but is separately provided with terminals (e.g., the flexible cable) configured to be connected when the housing is folded. Accordingly, the function of the housing may be realized without separate connector/wire assembly or separate soldering based on the direct connection between the PCBs.

The foldable electronic control device 100 generally includes a housing 110, a first board 120, a second board 130, and a flexible cable 140.

The housing 110 includes a body 111 and a cover 112 configured to be opened and closed in a foldable manner. The body 111 and the cover 112 have a structure in which the body 111 and the cover 112 are fastened to each other by snap fitting.

The body 111 is provided with an accommodation space therein to store electronic components. The body 111 includes an external connection connector 150 connected to the first board 120.

The cover 112 has a symmetrical structure with respect to the body 111. In addition, the cover 112 has an accommodation space therein. The cover 112 pivots about a connecting portion 113 having a hinge structure, and covers and fixes the body 111. The cover 112 may have a structure in which a portion of the cover 112 engaging with the connector 150 is depressed.

The first board 120 has function-specific configuration circuitry, and is fastened to the body 111.

The second board 130 has function-specific configuration circuitry, and is fastened to the cover 112.

The flexible cable 140 is a flexible printed circuit (FPC) electrically connecting the first board 120 and the second board 130, and is located on the connecting portion 113 between the body 111 and the cover 112.

The flexible cable 140 is fixed on the connecting portion 113 between the body 111 and the cover 112 while having the shape of the symbol ‘⊂’. That is, in the case of unfolding between the body 111 and the cover 112, the flexible cable 140 maintains the shape of the symbol ‘∩’. In the case of folding between the body 111 and the cover 112, the flexible cable 140 maintains the shape of the symbol ‘⊂’.

The flexible cable 140 may be fixed to the connecting portion 113 between the body 111 and the cover 112 by fusion. Here, the flexible cable 140 may be fused on the connecting portion 113 in a shape wrapping around the entirety of the connecting portion 113 between the body 111 and the cover 112.

In another example, the flexible cable 140 may be fastened to the connecting portion 113 between the body 111 and the cover 112 by, for example, bolting.

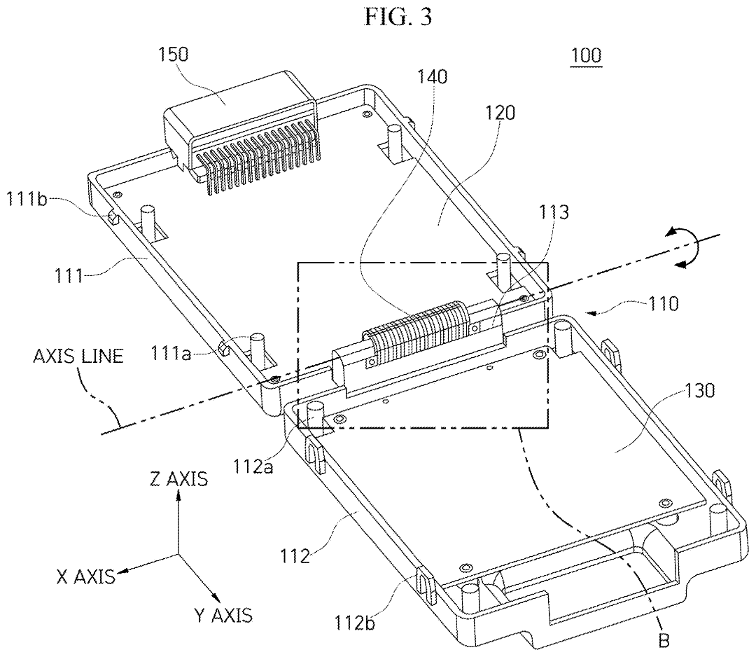

FIG. 3 is a perspective view schematically illustrating an unfolded shape of the foldable electronic control device according to embodiments of the present disclosure.

The body 111 and the cover 112 of the housing 110 are engaged with and fitted to each other by means of the connecting portion 113 having the hinge structure. That is, the housing 110 has a foldable structure in which the cover 112 covers the body 111 along the axis.

The body 111 includes a plurality of first backing rods 111a protruding therefrom to extend through predetermined portions of the first board 120.

The cover 112 includes a plurality of second backing rods 112a protruding therefrom to extend through predetermined portions of the second board 130.

When the cover 112 covers the body 111, the first backing rods 111a support the second board 130, and the second backing rods 112a support the first board 120. Accordingly, the first and second boards 120 and 130 stacked above each other when the housing 110 is folded may maintain durability due to the first and second backing rods 111a and 112a.

The body 111 may have a plurality of protrusions 111b on the outer circumferential portions. Here, the cover 112 may have a plurality of hooks 112b engaging with the protrusions 111b, respectively. When the housing 110 is folded, the body 111 and the cover 112 are fastened to each other by snap fitting, in which the protrusions 111b are detachably engaged with the hooks 112b, respectively.

The first board 120 and the second board 130 are disconnected from each other when the housing 110 is unfolded. When the housing 110 is folded, the first board 120 and the second board 130 are connected to each other while being stacked above each other. Here, the flexible cable 140 electrically connects the first board 120 and the second board 130 only when the housing 110 is folded.

Accordingly, the foldable electronic control device 100 does not provide a direct connection between the first and second boards 120 and 130. In the foldable electronic control device 100, the flexible cable 140 is provided separately so that the first and second boards 120 and 130 are connected by means of the flexible cable 140 only when the housing 110 is folded. Accordingly, the foldable electronic control device 100 may realize a foldable assembly structure without separate connector/wire assembly or separate soldering, due to the direct connection between the first and second boards 120 and 130.

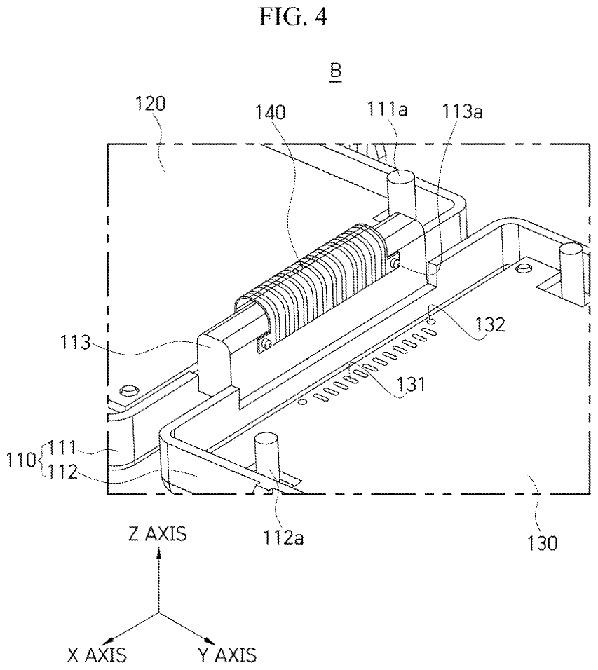

FIG. 4 is an enlarged view of the part B illustrated in FIG. 1.

Each of the first board 120 and the second board 130 may include flip-chip type solder bumps 131 on portions of the first and second boards 120, 130 engaging with the flexible cable 140.

The connecting portion 113 between the body 111 and the cover 112 includes a plurality of protrusions 113a on predetermined portions of the connecting portion 113.

Each of the first board 120 and the second board 130 may include a plurality of fixing recesses 132 configured to engage with the protrusions 113a.

The protrusions 113a are configured to extend through the flexible cable 140.

In another example, although not shown, the protrusions 113a may have a tapered structure, the width of which gradually decreases in the direction from the connecting portion 113 to the outside.

Predetermined outer circumferential portions of the protrusions 113a may be recessed to form fastening recesses (not shown) into which the flexible cable 140 is fitted. The fastening recesses may be engaged with the inner circumferential portions of assembly holes formed in both ends of the flexible cable 140.

Although the configuration of the present disclosure has been described in detail with respect to the example embodiments, this is for illustrative purposes only. Rather, the configuration of the present disclosure may be modified and changed variously within the scope of the technical idea of the present disclosure.

What is claimed is:

1. A foldable electronic control device comprising:
a housing comprising a body and a cover configured to be opened and closed in a foldable manner;
first and second boards fastened to the body and the cover, respectively, and configured to be disconnected from each other when the housing is unfolded and connected to each other when the housing is folded; and
a flexible cable electrically connecting the first board and the second board when the housing is folded.

2. The foldable electronic control device of claim 1, wherein the first and second boards are configured to be connected to each other in a stacked state when the housing is folded.

3. The foldable electronic control device of claim 1, wherein the flexible cable comprises a flexible printed circuit (FPC).

4. The foldable electronic control device of claim 1, wherein the flexible cable is fixed to a connecting portion between the body and the cover by fusion.

5. The foldable electronic control device of claim 1, wherein the flexible cable is fastened to a connecting portion between the body and the cover by bolting.

6. The foldable electronic control device of claim 1, wherein the flexible cable is fused to a connecting portion between the body and the cover while wrapping around the entire connecting portion.

7. The foldable electronic control device of claim 1, wherein the flexible cable is fixed to a connecting portion between the body and the cover while having a ‘⊂’ shape.

8. The foldable electronic control device of claim 1, wherein the flexible cable maintains a ‘∩’ shape in a case of unfolding between the body and the cover and maintains a ‘⊂’ shape in a case of folding between the body and the cover.

9. The foldable electronic control device of claim 1, wherein each of the first and second boards comprises flip-chip type solder bumps on a portion of the first and second boards engaging with the flexible cable.

10. The foldable electronic control device of claim 1, wherein the body comprises a plurality of first backing rods protruding from the body to extend through predetermined portions of the first board,
the cover comprises a plurality of second backing rods protruding therefrom to extend through predetermined portions of the second board, and
when the cover covers the body, the first backing rods support the second board, and the second backing rods support the first board.

11. The foldable electronic control device of claim 1, wherein the body comprises an external connection connector connected to the first board, and
the cover has a structure in which a portion of the cover engaging with the connector is depressed.

12. A vehicle comprising the foldable electronic control device of claim 1.

13. A foldable electronic control device comprising:
a housing comprising a body having an accommodation space in the body and a cover configured to cover the body in a foldable manner;
a first board connected to the body;
a second board connected to the cover; and
a flexible cable electrically connecting the first board and the second board,
wherein the flexible cable is located on a connecting portion between the body and the cover.

14. The foldable electronic control device of claim 13, wherein the housing has a structure in which the body and the cover are fastened to each other by snap fitting.

15. The foldable electronic control device of claim 13, wherein each of the first and second boards comprises flip-chip type solder bumps on a portion of the first and second boards engaging with the flexible cable.

16. The foldable electronic control device of claim 13, wherein the connecting portion between the body and the cover comprises a plurality of protrusions on predetermined portions, and
each of the first and second boards comprises a plurality of fixing recesses configured to engage with the protrusions.

17. The foldable electronic control device of claim 16, wherein the protrusions are configured to extend through the flexible cable.

18. The foldable electronic control device of claim 16, wherein each of the protrusions has a tapered structure, a width of which gradually decreases in an outward direction from the connecting portion.

19. The foldable electronic control device of claim 16, wherein predetermined outer circumferential portions of the protrusions are depressed to form fastening recesses into which the flexible cable is fitted.

20. A vehicle comprising the foldable electronic control device of claim 13.
